(19) United States
(12) Patent Application Publication
(10) Pub. No.: US 2012/0007033 A1
(43) Pub. Date: Jan. 12, 2012

(54) PHASE-CHANGE MEMORY DEVICE AND METHOD OF MANUFACTURING THE SAME

(76) Inventor: Min Seok KIM, Ichon-si (KR)

(21) Appl. No.: 12/976,239

(22) Filed: Dec. 22, 2010

(30) Foreign Application Priority Data
Jul. 6, 2010 (KR) 10-2010-0064867

(51) Int. Cl. H01L 45/00; H01L 21/02

(52) U.S. Cl. 257/2; 438/382; 257/E45.001; 257/E21.004

(57) ABSTRACT

A phase-change memory device and a method of manufacturing the same are provided. The method of manufacturing the phase-change memory device includes forming a heating electrode, having a pillar shape, on a semiconductor substrate, and forming a phase-change pattern passing through an upper surface of the heating electrode. A sidewall of the phase-change pattern is in contact with the upper surface of the heating electrode.

### CROSS-REFERENCES TO RELATED APPLICATION

The present application claims priority under 35 U.S.C. 119(a) to Korean patent application number 10-2010-0064867, filed on Jul. 6, 2010, in the Korean Patent Office, which is incorporated by reference in its entirety.

### BACKGROUND OF THE INVENTION

1. Technical Field

The inventive concept relates to a non-volatile semiconductor memory device and a method of manufacturing the same, and more particularly, to a phase-change memory device and a method of manufacturing the same.

2. Related Art

As IT technologies develop, demand for next generation memory devices, which have ultra-high speed and high capacity and which are suitable for mobile information communication systems, is increasing. That is, it is desired that the next generation memory devices have a high speed operation as in static random access memories (SRAMs), and a high integration degree as in dynamic RAMs (DRAMs), while consuming less power. As the next generation memory devices, Ferroelectric RAMs (FRAMs), Magnetic RAMs (MRAMs), phase-change RAMs (PRAMs, hereinafter, referred to as phase-change memory devices) or nano floating gate memories (NFGMs) with excellent power consumption, data retention, and write/read characteristics as compared with conventional memory devices, have been considered. Among these, the phase-change memory devices, having a simple structure, are fabricated at a lower cost and operate at a high speed.

The phase-change memory devices include phase-change layers of which crystalline states are changed by heat generated by an applied current. A chalcogenide (GST)-based material which is comprised of germanium (Ge), antimony (Sb) and tellurium (Te) is typically used as the phase-change layer of the phase-change memory devices. The crystalline state of a phase-change layer, such as a GST layer, is changed by the heat generated according to an intensity of a supplied current and a current supply time. The phase-change layer has a higher resistance at an amorphous state and a lower resistance at a crystalline state such that it can be used as a data storage medium of a memory device.

The phase-change layer is phase-changed by providing heat from a heating electrode (or, bottom electrode contact (BEC)) disposed under the phase-change layer. The heating electrode receives a very large ‘on’ current from the switching device disposed below the heating electrode and provides the heat to the phase-change layer as much as possible. Accordingly, the phase-change layer preferably is formed of a high specific resistivity material and has a relatively small contact area with the heating electrode.

Furthermore, the contact area between the phase-change layer and the heating electrode should be uniform so that the uniformity of the phase-changing can be ensured.

### SUMMARY

According to an exemplary embodiment, a phase-change memory device includes a semiconductor substrate, a heating electrode formed on the semiconductor substrate and having a pillar shape, and a phase-change pattern passing through an upper surface of the heating electrode, wherein a sidewall of the phase-change pattern is in contact with the upper surface of the heating electrode.

According to another exemplary embodiment, a method of manufacturing a phase-change memory device includes forming a heating electrode, having a pillar shape, on a semiconductor substrate, and forming a phase-change pattern passing through an upper surface of the heating electrode, wherein a sidewall of the phase-change pattern is in contact with the upper surface of the heating electrode.

According to another exemplary embodiment, a method of manufacturing a phase-change memory device includes forming a first interlayer insulating layer having a contact hole on a semiconductor substrate, forming a first heating electrode portion on an inner surface of the contact hole, forming an insulating spacer on a sidewall of the first heating electrode portion, filling the contact hole with a second interlayer insulating layer, forming a second heating electrode portion to shield the contact hole, forming a second insulating layer on the second heating electrode portion, etching the second insulating layer, the second heating electrode portion, and the second interlayer insulating layer to form a second hole, and forming a phase-change pattern within the second hole.

These and other features, aspects, and embodiments are described below in the section entitled “DESCRIPTION OF EXEMPLARY EMBODIMENTS”.

### BRIEF DESCRIPTION OF THE DRAWINGS

The above and other aspects, features and advantages of the subject matter of the present disclosure will be more clearly understood from the following detailed description and the accompanying drawings, in which:

FIGS. 1 to 7 are cross-sectional views illustrating a method of manufacturing a phase-change memory device according to an exemplary embodiment of the inventive concept;

FIG. 8 is a top view of a phase-change memory device according to an exemplary embodiment of the inventive concept; and

FIG. 9 is a perspective view showing the cylindrical shape of a portion of a phase-change pattern and a second interlayer insulating layer included in a phase-change memory device according to an exemplary embodiment of the inventive concept.

### DESCRIPTION OF EXEMPLARY EMBODIMENTS

Exemplary embodiments are described herein with reference to the accompanying drawings. One of ordinary skill in the art should understand that variations from the shapes of the illustrations as a result, for example, of manufacturing techniques and/or tolerances, are to be expected. Thus, exemplary embodiments should not be construed as limited to the particular shapes of regions illustrated herein. In the drawings, lengths and sizes of layers and regions may be exaggerated for clarity. Like reference numerals in the drawings denote like elements. Herein, it should also be understood that when a layer is referred to as being “on” another layer or substrate, it can be directly on the other layer or substrate, or intervening layers may also be present.

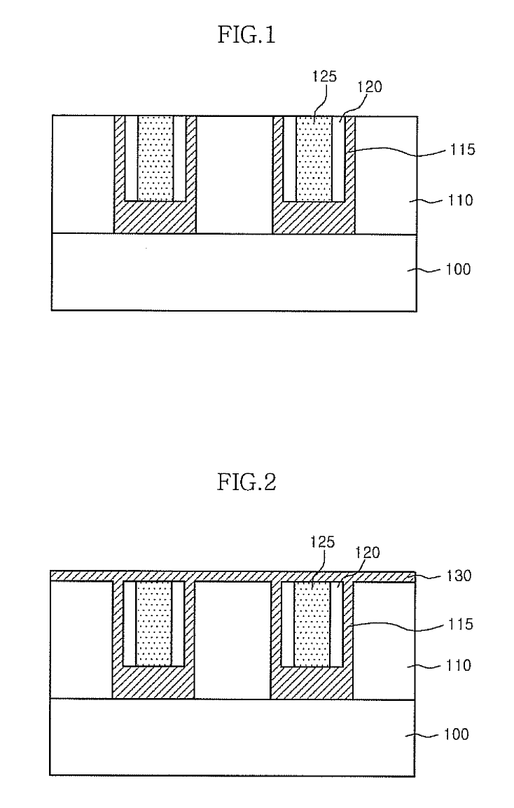

Referring to FIG. 1, a semiconductor substrate 100 including a word line and a switching device (not shown) is provided. A first interlayer insulating layer 110 is formed on the semiconductor substrate 100.

A contact hole for defining a heating electrode region is formed in the first interlayer insulating layer 110. A first conduction layer is uniformly deposited on a surface of the first interlayer insulating layer 110 including the contact hole. The first conduction layer may be formed of a conduction material including a high specific resistivity. For example, the first conduction layer may be formed of a titanium nitride layer. The first conduction layer is etched back to remain within the contact hole, thereby forming a first heating electrode portion 115 on an inner surface of the contact hole.

A first insulating layer is deposited over the first interlayer insulating layer 110 in which the first heating electrode portion 115 is formed. Then, the first insulating layer is anisotropically etched so that a portion of the first insulating layer remains on a sidewall of the contact hole, thereby forming an insulating spacer 120 on a sidewall of the first heating electrode portion 115. A second interlayer insulating layer 125 is buried within the contact hole having the insulating spacer 120 formed therein. Herein, the first insulating layer may be a silicon nitride layer having an excellent heat-endurance.

Referring to FIG. 2, a second conduction layer 130 is deposited on the first and second interlayer insulating layers 110 and 125 and the insulating spacer 120. The second conduction layer 130 may be the same material as the first conduction layer and may be formed at a relatively thinner thickness than the first conduction layer. In addition, since the second conduction layer 130 is formed on a flat surface by a deposition method, the thickness of the second conduction layer 130 can be controlled. Furthermore, because present deposition technology allows a thickness to be controlled at an angstrom level, the second conduction layer 130 may be deposited uniformly. Accordingly, the second conduction layer 130 can be uniformly deposited at a thickness below the exposure limit of an exposing equipment.

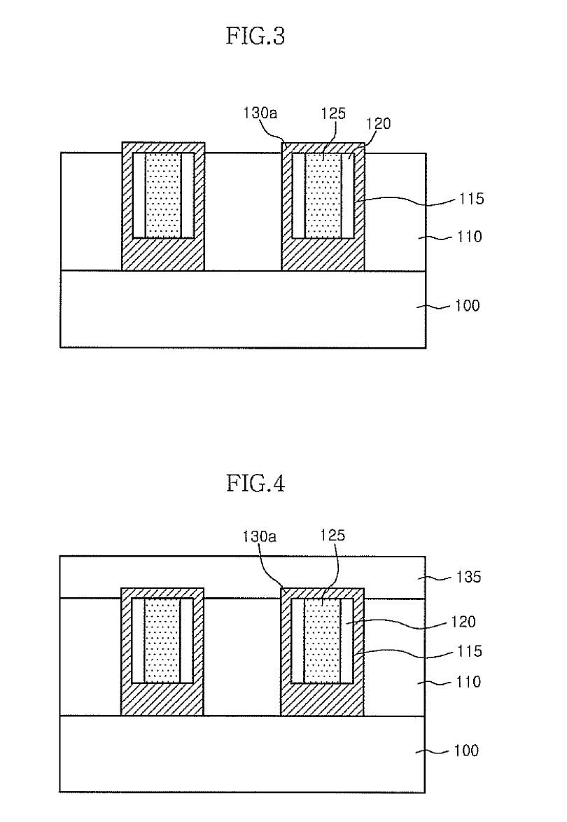

Referring to FIG. 3, the second conduction layer 130 is patterned to shield the contact hole, thereby forming a second heating electrode portion 130a. That is, the second conduction layer 130 is patterned to be in contact with a surface of the second interlayer insulating layer 125, a surface of the insulating spacer 120, and a surface of the first heating electrode portion 115. Accordingly, the first and second heating electrode portions 115 and 130a together form a pillar with the second interlayer insulating layer 125 and the insulating spacer 120 inside. In other words, the first and second heating electrode portions 115 and 130a together may have a hexahedral shape.

Referring to FIG. 4, a second insulating layer 135 is deposited on a resultant surface of the semiconductor substrate 100 on which the second heating electrode portion 130a is formed. The second insulating layer 135 may be the same material as the first insulating layer used to form the insulating spacer 120.

Referring to FIG. 5, the second insulating layer 135, the second heating electrode portion 130a, and the second interlayer insulating layer 125 are partially etched to form a second hole 139 having a certain depth. As a result of forming the second hole 139, a heating electrode 140 is also formed. The heating electrode 140 includes the etched first heating electrode portion 115 and the etched second heating electrode portion 130a, and therefore, still has the pillar shape, except that at this time the second hole 139 has created an opening in the upper portion of the pillar. Herein, the reference number 135a denotes the second insulating layer 135 remaining after being patterned to form the heating electrode 140.

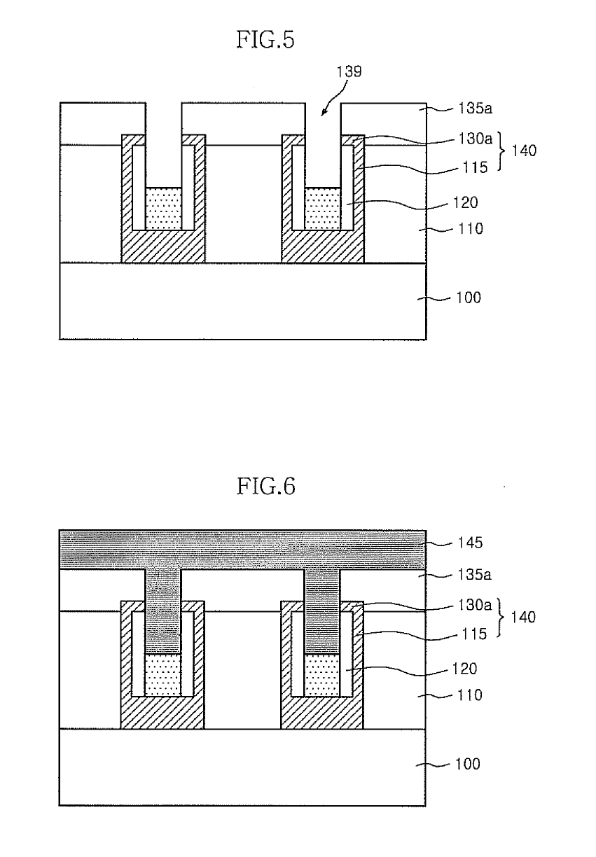

Referring to FIG. 6, a phase-change material layer 145 is deposited to fill the second hole 139. The phase-change material layer 145 may be a GST material.

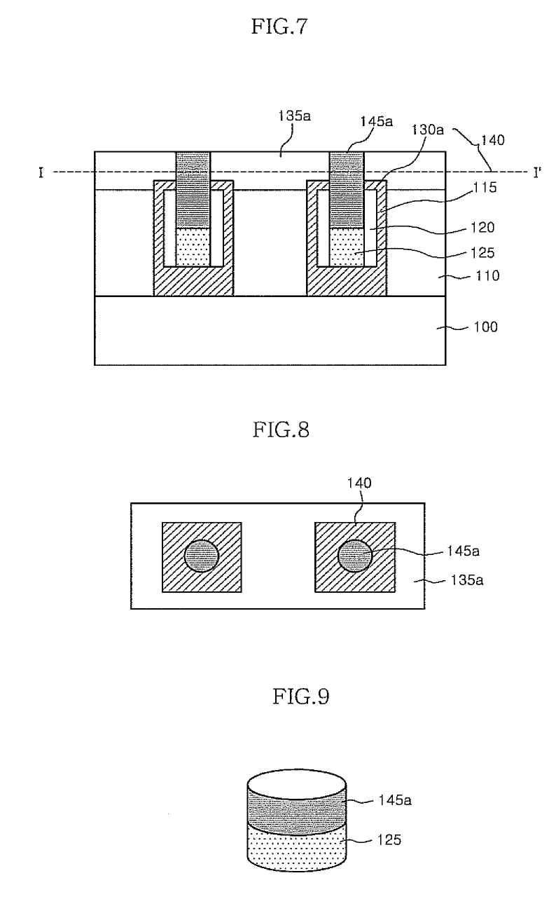

Referring to FIG. 7, the phase-change material layer 145 may be planarized to expose a surface of the second insulating layer 135a, thereby forming a phase-change pattern 145a confined to the opening that was created by the second hole 139.

FIG. 8 shows a top view of the cross section taken along line I-I′ in FIG. 7. Referring to the top view shown in FIG. 8, it can be understood that the phase-change pattern 145a has a cylindrical shape and is fixed within the heating electrode 140 having the pillar shape.

As shown in FIG. 9, the phase-change pattern 145a and the second interlayer insulating layer 125 may have cylindrical shapes within the pillar shaped heating electrode 140.

At this time, the phase-change pattern 145a is substantially formed so that a portion of a sidewall surface of the phase-change pattern 145a is in contact with an upper surface of the heating electrode 140. More specifically, the phase-change pattern 145a is in contact with the second heating electrode portion 130a of the heating electrode 140. At this time, a contact portion between the phase-change pattern 145a and the heating electrode 140 may be uniformly controlled by the controlling the deposition thickness of the second conduction layer 130 so that a contact area between the phase-change pattern 145a and the heating electrode 140 can be uniformly obtained.

According to the inventive concept as described above, the heating electrode of the phase-change memory device has a pillar shape and the phase-change pattern penetrates through the upper portion of the heating electrode. Accordingly, the sidewall of the phase-change pattern is in contact with the upper surface of the heating electrode. Moreover, the heating electrode is formed to have a uniformly flat upper surface so that a uniform contact area between the phase-change pattern and the sidewall surface of the phase-change pattern can be obtained.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A phase-change memory device, comprising:
a semiconductor substrate;
a heating electrode formed on the semiconductor substrate and having a pillar shape; and
a phase-change pattern passing through an upper surface of the heating electrode,
wherein a sidewall of the phase-change pattern is in contact with the upper surface of the heating electrode.

2. The phase-change memory device of claim 1, wherein the heating electrode has a hexahedral shape.

3. The phase-change memory device of claim 2, wherein an insulating layer is interposed between the sidewall of the heating electrode and the phase-change pattern.

4. The phase-change memory device of claim 2, wherein an insulating layer is interposed between the phase-change pattern and a bottom portion of the heating electrode.

5. A method of manufacturing a phase-change memory device, comprising:
forming a heating electrode, having a pillar shape, on a semiconductor substrate; and
forming a phase-change pattern passing through an upper surface of the heating electrode,
wherein a sidewall of the phase-change pattern is in contact with the upper surface of the heating electrode.

6. The method of claim 5, wherein the forming of the heating electrode, comprises:
forming a contact hole;
forming a first heating electrode portion in the contact hole;
filling the remainder of the contact hole; and
forming a second heating electrode portion over the filled contact hole,
wherein the second heating electrode portion is the upper surface of the heating electrode.

7. The method of claim 6, wherein the first and second heating electrode portions are formed from the same material.

8. A method of manufacturing a phase-change memory device, comprising:
forming a first interlayer insulating layer having a contact hole on a semiconductor substrate;
forming a first heating electrode portion on an inner surface of the contact hole;
forming an insulating spacer on a sidewall of the first heating electrode portion;
filling the contact hole with a second interlayer insulating layer;
forming a second heating electrode portion to shield the contact hole;
forming a second insulating layer on the second heating electrode portion;
etching the second insulating layer, the second heating electrode portion, and the second interlayer insulating layer to form a second hole; and
forming a phase-change pattern within the second hole.

9. The method of claim 8, wherein the forming of the second heating electrode portion to shield the contact hole is performed by a deposition process.

10. The method of claim 9, wherein the deposition process is controlled to form the second heating electrode portion to a desired thickness.
